(19) United States
(12) Patent Application Publication
(10) Pub. No.: US 2026/0187433 A1
(43) Pub. Date: Jul. 2, 2026

(54) SPINTRONIC DEVICE, ARRAY, AND METHOD FOR OPTIMIZING RECURSIVE NEURAL NETWORK

(71) Applicant: Institute of Microelectronics, Chinese Academy of Sciences, Beijing (CN)

(72) Inventors: Guozhong XING, Beijing (CN); Huai LIN, Beijing (CN); Ming Liu, Beijing (CN)

(21) Appl. No.: 18/565,448

(22) PCT Filed: Sep. 5, 2022
(86) PCT No.: PCT/CN2022/117035

§ 371 Date: Nov. 29, 2023

(51) Int. Cl. G06N 3/063; G06N 3/044; H10N 50/10

(52) U.S. Cl. CPC G06N 3/063; G06N 3/044; H10N 50/10

(57) ABSTRACT

A spintronic device, an array, and a method for optimizing a recursive neural network are provided. The spintronic device includes: a magnetic domain device with a preset thickness, wherein the magnetic domain device is configured to form a labyrinth-like magnetic domain structure under a modulation of a Dzyaloshinskii-Moriya interaction and a dipole interaction, the labyrinth-like magnetic domain structure includes a plurality of magnetic domain regions with random magnetic domain directions, and a boundary between adjacent two magnetic domain regions is a magnetic domain wall; a heterogenous thin film of at least one cycle, wherein the heterogenous thin film is disposed on a first surface of the magnetic domain device; at least four electrodes disposed on a second surface of the magnetic domain device, wherein the four electrodes are respectively connected to different magnetic domain regions.

### TECHNICAL FIELD

Embodiments of the present disclosure relate to a field of magnetic domain wall technology, and in particular, to a spintronic device based on a magnetic domain wall, an array, and a method for optimizing a recursive neural network.

### BACKGROUND

In an implementation of integrated storage and computing functions, a logic operation of a spintronic device based on a magnetic domain wall mainly relies on a combination with a transistor to form a hybrid operation circuit, including a use of transistors to achieve a basic Boolean logic operation; alternatively, with an assistance of an external read and write circuit, a logical operation and storage may be completed within a memory cell itself, avoiding a “memory wall bottleneck” that exists in a traditional von Neumann structure.

Spintronic information devices such as STT-MRAM or SOT-MRAM have received widespread attention due to their high-speed and high durability characteristics. However, they are limited by binary weight modulation, and SOT-MRAM requires an additional external magnetic field to assist in writing information, which is not conducive to device integration.

In a process of implementing a concept of the present disclosure, the inventor discovers at least the following problems in the relevant technology: in an existing spintronic device based on the magnetic domain wall, a direction of the magnetic domain is unified and unidirectional, and needs to be generated and driven by an assistance of an external field. Therefore, the spintronic device has low resistance changes and system complexity under an action of an electric pulse, which is not conducive to the modulation of multivalued weights and integrated applications in large-scale circuits.

### SUMMARY

In view of this, the embodiments of the present disclosure provide a spintronic device based on a magnetic domain wall, an array, and a method for optimizing a recursive neural network.

An aspect of the embodiments of the present disclosure provides a spintronic device based on a magnetic domain wall, including:
a magnetic domain device, wherein the magnetic domain device is configured to form a labyrinth-like magnetic domain structure under a modulation of a Dzyaloshinskii-Moriya interaction and a dipole interaction, the labyrinth-like magnetic domain structure includes a plurality of magnetic domain regions located randomly, and a boundary between adjacent two magnetic domain regions is the magnetic domain wall;
a heterogenous thin film of at least one cycle, wherein the heterogenous thin film is disposed on a first surface of the magnetic domain device;
at least four electrodes disposed on a second surface of the magnetic domain device, wherein the four electrodes are respectively connected to different magnetic domain regions.

According to the embodiments of the present disclosure, the magnetic domain device includes a heavy metal layer and a magnetic layer with a preset thickness, wherein a range of the preset thickness of the magnetic layer is 1.1 nm to 1.4 nm, a heterostructure composed of the magnetic layer and the heavy metal layer generates the Dzyaloshinskii-Moriya interaction and the dipole interaction, so as to generate the labyrinth-like magnetic domain structure in a transition region of vertical anisotropy and in-plane anisotropy.

According to the embodiments of the present disclosure, the magnetic domain device includes at least two heterostructures stacked periodically.

According to the embodiments of the present disclosure, the heavy metal layer is made of at least one of: Pt, W, Ta, Ru, Au, Ir, or Pd;
the magnetic layer is made of at least one of: CoFeB, CoFe, NiFe, IrMn, GdFeCo, Co, Fe, two-dimensional CrI₃, or Fe₃GeTe₂;
in a case that the magnetic domain device includes a barrier layer, the barrier layer is made of at least one of: MgO, AlₓO_{y}, or h-BN, wherein each of x and y is an integer greater than 0.

Another aspect of the embodiments of the present disclosure provides an array based on a spintronic device, including:
a plurality of line groups arranged horizontally spaced, wherein each of the plurality of line groups includes a source line, a first word line and a second word line arranged horizontally from top to bottom, and the first word line and the second word line are spaced at a preset distance;
a plurality of bit lines arranged vertically spaced, wherein two adjacent bit lines, and the first word line and the second word line in each line group form a placement region;
a plurality of spintronic devices mentioned above, wherein one spintronic device is disposed in each placement region;
wherein a connection method of the spintronic device and the line group and bit line corresponding to the placement region includes:
at least two of the at least four electrodes are connected to one bit line, remaining at least two of the at least four electrodes are respectively connected to the source line and the second word line in one line group, and the at least two electrodes connected to the bit line are respectively connected to the first word line and the second word line.

According to the embodiments of the present disclosure, the at least two electrodes connected to the bit line are respectively connected to the first word line and the second word line through a transistor.

According to the embodiments of the present disclosure, the electrode connected to the bit line and the first word line is connected to the spintronic device through a first connection point on the spintronic device, and the electrode connected to the source line is connected to the spintronic device through a second connection point on the spintronic device;
the electrode connected only to the second word line is connected to the spintronic device through a third connection point on the spintronic device, and the electrode connected to the bit line and the second word line is connected to the spintronic device through a fourth connection point on the spintronic device.

Another aspect of the embodiments of the present disclosure provides a method for optimizing a recursive neural network implemented in hardware, applied to the array mentioned above, wherein a weight of the recursive neural network is mapped to the array, the array stores the weight of the recursive neural network, and the method includes:
for each spintronic device in the array, when the first word line connected to the spintronic device is at a high level and the bit line is grounded, an electrical (voltage or current) pulse in the source line drives a motion of the magnetic domain wall through a first node and a second node, so as to reduce the weight of the recursive neural network, wherein the first node refers to a connection point of the electrode connected to the bit line and the first word line on the spintronic device, and the second node refers to a connection point of the electrode connected to the source line on the spintronic device;
when the second word line is at a high level and the bit line is grounded, the electrical pulse in the source line drives the motion of the magnetic domain wall through a third node and a fourth node, so as to increase the weight of the recursive neural network, wherein the third node refers to a connection point of the electrode connected only to the second word line on the spintronic device, and the fourth node refers to a connection point of the electrode connected to the bit line and the second word line on the spintronic device.

According to the embodiments of the present disclosure, during a spontaneous magnetization process of the spintronic device, the heterogeneous thin film promotes the formation of labyrinth-like magnetic domain structure within the magnetic domain device, forming randomly distributed magnetic domain walls within the magnetic domain device. Therefore, under an action of an electrical pulse, a direction of the magnetic domain within the labyrinth-like magnetic domain structure undergoes significant changes with a magnitude of an electrical pulse current, resulting in a larger range of resistance changes in the spintronic device, which facilitates continuous weight modulation.

### BRIEF DESCRIPTION OF THE DRAWINGS

The above and other objectives, features, and advantages of the present disclosure will be clearer through the following descriptions of embodiments of the present disclosure with reference to accompanying drawings, in which:

FIG. 1 schematically shows a structural diagram of a spintronic device according to the embodiments of the present disclosure;

FIG. 2 schematically shows a structural diagram of an array according to the embodiments of the present disclosure;

FIG. 3 schematically shows an optimization effect of the Hopfield network in solving a traveling salesman problem according to the embodiments of the present disclosure;

FIG. 4 schematically shows a weight modulation diagram of the Hopfield network according to the embodiments of the present disclosure.

### DETAILED DESCRIPTION OF EMBODIMENTS

The following provides a further detailed explanation of the present disclosure in conjunction with the accompanying drawings and the embodiments. It may be understood that the specific embodiments described here are only used to explain the present disclosure, but not to limit the present disclosure. The various features recited in the embodiments may be combined to form a plurality of alternative solutions. Furthermore, it should be noted that for the convenience of description, the accompanying drawings only show some parts related to the present disclosure rather than the entire structure.

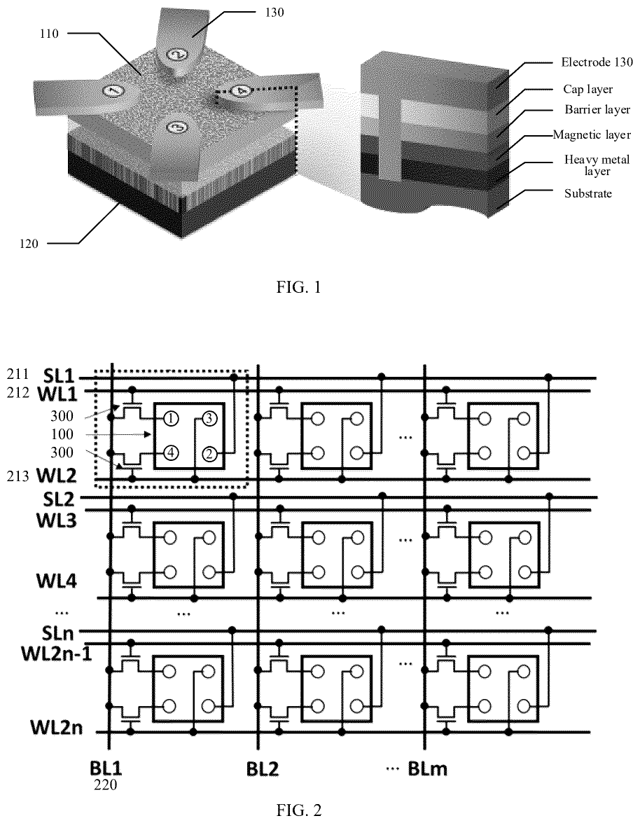

FIG. 1 schematically shows a structural diagram of a spintronic device 100 according to the embodiments of the present disclosure.

As shown in FIG. 1, the spintronic device 100 based on a magnetic domain wall includes a magnetic domain device 110, a heterogenous thin film 120 of at least one cycle, and at least four electrodes 130.

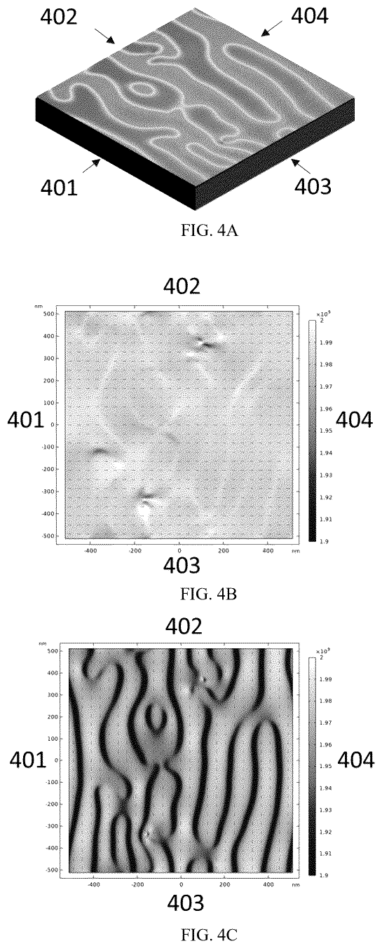

The magnetic domain device 110 is used to form a labyrinth-like magnetic domain structure under a modulation of a Dzyaloshinskii-Moriya interaction and a dipole interaction which are formed with a heavy metal layer. The labyrinth-like magnetic domain structure includes a plurality of magnetic domain regions with opposite directions (see irregular regions in FIG. 4(a)), and a boundary between adjacent two magnetic domain regions is the magnetic domain wall. The heterogenous thin film 120 is disposed on a first surface of the magnetic domain device 110. At least four electrodes 130 are disposed on a second surface of the magnetic domain device 110, and the four electrodes 130 are respectively connected to different magnetic domain regions.

According to the embodiments of the present disclosure, the magnetic domain regions are small magnetized regions with various directions generated and differentiated to reduce a static magnetic energy during a spontaneous magnetization process of a ferromagnetic material. Each region contains a large number of atoms, whose magnetic moments are arranged neatly like small magnets, but directions of atomic magnetic moment arrangements between adjacent different regions are different. An interface between various magnetic domain regions is called the magnetic domain wall.

According to the embodiments of the present disclosure, the labyrinth-like magnetic domain structure may refer to a periodic magnetic domain structure formed by up and down alternating magnetization directions of a plurality of magnetic domain regions.

According to the embodiments of the present disclosure, when a material containing a ferromagnetic or antiferromagnetic interface is cooled to Darnell temperature in a magnetic field, a unidirectional anisotropy phenomenon occurred in the ferromagnetic material is called an exchange coupling. At an atomic interface between a heavy metal layer and a magnetic layer, there is a Dzyaloshinskii-Moriya interaction (abbreviated as DMI) that causes adjacent magnetization perpendicular.

According to the embodiments of the present disclosure, the dipole interaction is the most common type of interaction between polar molecules, that is, an attraction between a partially positively charged end of a polar molecule and a partially negatively charged end of another molecule.

According to the embodiments of the present disclosure, the heterogenous thin film 120 is used to promote the formation of the labyrinth-like magnetic domain structure in the magnetic layer of the magnetic domain device under the modulation of anti-symmetric exchange coupling and dipole interaction.

According to the embodiments of the present disclosure, Ion Bean Etching (IBE) may be used to etch a through hole on the heterogenous thin film 120, and the electrode 130 is fabricated by using an electron beam deposition method.

According to the embodiments of the present disclosure, the first surface may refer to a lower surface of the magnetic domain device 110, and the second surface may refer to an upper surface of the magnetic domain device 110.

According to the embodiments of the present disclosure, during a spontaneous magnetization process of the spintronic device, the heterogeneous thin film promotes the formation of labyrinth-like magnetic domain structure within the magnetic domain device, forming randomly distributed magnetic domain walls within the magnetic domain device. Therefore, under an action of an electrical pulse, a direction of the magnetic domain within the labyrinth-like magnetic domain structure undergoes significant changes with a magnitude of an electrical pulse current, resulting in a larger range of resistance changes in the spintronic device, which facilitates continuous weight modulation.

According to the embodiments of the present disclosure, the magnetic domain device includes a heavy metal layer and a magnetic layer with a preset thickness, wherein a range of the preset thickness of the magnetic layer is 1.1 nm to 1.4 nm, a heterostructure composed of the magnetic layer and the heavy metal layer generates the Dzyaloshinskii-Moriya interaction and the dipole interaction, so as to generate the labyrinth-like magnetic domain structure in a transition region of vertical anisotropy and in-plane anisotropy.

According to the embodiments of the present disclosure, the magnetic domain device 110 within the above range may cause the magnetic domain device 110 to generate the above labyrinth-like magnetic domain structure, so as to adjust the resistance value of the spintronic device 100 in a large range.

According to the embodiments of the present disclosure, the heavy metal layer and the magnetic layer may be stacked periodically, so as to form the magnetic domain device 110. In another exemplary embodiment, the magnetic domain device 110 includes a substrate, a heterostructure, and a capping layer. The heterostructure sequentially includes a heavy metal layer, a magnetic layer, and a barrier layer from bottom to top, as shown in FIG. 1.

According to the embodiments of the present disclosure, the magnetic domain device 110 includes at least two heterostructures stacked periodically.

According to the embodiments of the present disclosure, the labyrinth-like magnetic domain structure is formed in the magnetic layer through the Dzyaloshinskii-Moriya interaction and the dipole interaction.

According to the embodiments of the present disclosure, the heavy metal layer is made of at least one of: Pt, W, Ta, Ru, Au, Ir, or Pd.

The magnetic layer is made of at least one of: CoFeB, CoFe, NiFe, IrMn, GdFeCo, Co, Fe, two-dimensional CrI₃, or Fe₃GeTe₂.

In a case that the magnetic domain device 110 includes a barrier layer, the barrier layer is made of at least one of: MgO, AlₓO_{y}, or h-BN, wherein each of x and y is an integer greater than 0.

FIG. 2 schematically shows a structural diagram of an array according to the embodiments of the present disclosure.

As shown in FIG. 2, the array based on the spintronic device 100 includes a plurality of line groups 210 arranged horizontally spaced, a plurality of bit lines 220 arranged vertically spaced, and a plurality of spintronic devices 100.

Each of the plurality of line groups 210 includes a source line 211 (SLn in FIG. 2, n is an integer greater than 0), a first word line 212 and a second word line 213 (WL2n-1 and WL2n in FIG. 2, n is an integer greater than 0) arranged horizontally from top to bottom, and the first word line 212 and the second word line 213 are spaced at a preset distance. Two adjacent bit lines (BLm in FIG. 2, m is an integer greater than 0), and the first word line 212 and the second word line 213 in each line group 210 form a placement region. One spintronic device 100 is disposed in each placement region.

A connection method of the spintronic device 100 and the line group 210 and bit line 220 corresponding to the placement region includes: at least two of the at least four electrodes 130 are connected to one bit line 220, remaining at least two of the at least four electrodes 130 are respectively connected to the source line 211 and the second word line 213 in one line group 210, and the at least two electrodes 130 connected to the bit line 220 are respectively connected to the first word line 212 and the second word line 213.

According to the embodiments of the present disclosure, the array may be an m*n array integration formed by using a plurality of spintronic devices 100.

According to the embodiments of the present disclosure, the at least two electrodes 130 connected to the bit line 220 are respectively connected to the first word line 212 and the second word line 213 through a transistor 300.

According to the embodiments of the present disclosure, one spintronic device 100 forms a 2T1R structure through two transistors 300, and the 2T1R structure may serve as a basic unit of the array, wherein T refers to the transistor 300 and R refers to the spintronic device 100.

According to the embodiments of the present disclosure, during a spontaneous magnetization process of the spintronic device, the heterogeneous thin film promotes the formation of labyrinth-like magnetic domain structure within the magnetic domain device, forming randomly distributed magnetic domain walls within the magnetic domain device. Therefore, under an action of an electrical pulse, a direction of the magnetic domain within the labyrinth-like magnetic domain structure undergoes significant changes with a magnitude of an electrical pulse current, resulting in a larger range of resistance changes in the spintronic device, which facilitates continuous weight modulation.

According to the embodiments of the present disclosure, the electrode 130 connected to the bit line 220 and the first word line 212 is connected to the spintronic device 100 through a first connection point on the spintronic device 100, and the electrode 130 connected to the source line 211 is connected to the spintronic device 100 through a second connection point on the spintronic device 100.

According to the embodiments of the present disclosure, the electrode 130 connected only to the second word line 213 is connected to the spintronic device 100 through a third connection point on the spintronic device 100, and the electrode 130 connected to the bit line 220 and the second word line 213 is connected to the spintronic device 100 through a fourth connection point on the spintronic device 100.

According to the embodiments of the present disclosure, the four connection points may be located at four endpoints of a rectangle, wherein first and second connection points are located at two endpoints of one diagonal of the rectangle, and third and fourth connection points are located at two endpoints of the other diagonal of the rectangle.

In the embodiments of the present disclosure, a method for optimizing a recursive neural network implemented in hardware is applied to the array mentioned above. A weight of the recursive neural network is mapped to the array, the array stores the weight of the recursive neural network, and the method includes the following operations.

For each spintronic device 100 in the array, when the first word line 212 connected to the spintronic device 100 is at a high level and the bit line 220 is grounded, an electrical pulse in the source line 211 drives a motion of the magnetic domain wall through a first node and a second node, so as to reduce the weight of the recursive neural network, wherein the first node refers to a connection point of the electrode 130 connected to the bit line 220 and the first word line 212 on the spintronic device 100, and the second node refers to a connection point of the electrode 130 connected to the source line 211 on the spintronic device 100.

When the second word line 213 is at a high level and the bit line 220 is grounded, the electrical pulse in the source line 211 drives the motion of the magnetic domain wall through a third node and a fourth node, so as to increase the weight of the recursive neural network, wherein the third node refers to a connection point of the electrode 130 connected only to the second word line 213 on the spintronic device 100, and the fourth node refers to a connection point of the electrode 130 connected to the bit line 220 and the second word line 213 on the spintronic device 100.

According to the embodiments of the present disclosure, the first node is the first connection point (see \textcircled{1} in FIG. 2), the second node is the second connection point (see \textcircled{2} in FIG. 2), the third node is the third connection point (see \textcircled{3} in FIG. 2), and the fourth node is the fourth connection point (see \textcircled{4} in FIG. 2).

According to the embodiments of the present disclosure, when using the array composed of the spintronic device 100 to implement the method for optimizing the recursive neural network, during a spontaneous magnetization process of the spintronic device 100, the heterogeneous thin film 120 promotes the formation of labyrinth-like magnetic domain structure within the magnetic domain device 110 with a preset thickness, forming randomly distributed magnetic domain walls within the magnetic domain device 110. Therefore, under an action of an electrical pulse, a direction of the magnetic domain within the labyrinth-like magnetic domain structure undergoes significant changes with a magnitude of an electrical pulse current, resulting in a larger range of resistance changes in the spintronic device 100, which facilitates continuous weight modulation of the recursive neural network.

According to the embodiments of the present disclosure, when performing a weight reduction task, the bit line 220 (BLm) is grounded, the first word line 212 (such as WL1) is at a high level, and the electrical pulse drives the motion of the magnetic domain wall through the first node and the fourth node, so as to achieve a purpose of weight reduction. When performing a weight increase task, the bit line 220 (BLm) is grounded, the second line 213 (such as WL2) is at a high level, and the electrical pulse drives the motion of the magnetic domain wall through the second node and the third node, so as to achieve a purpose of weight increase. When performing a weight multiplication and addition (read) task, the bit line 220 (BLm) applies a read voltage, and the source line 211 (such as SL1) is at a high level. At this point, the current density is not sufficient to drive the motion of the magnetic domain wall. The read voltage generates a read current at the first node and the fourth node, which is then aggregated and read by an external device.

According to the embodiments of the present disclosure, during the process of weight change, the change in current direction causes the direction of the magnetic domain to change, resulting in a change in the resistance value of the magnetic domain device 110, ultimately affecting the weight.

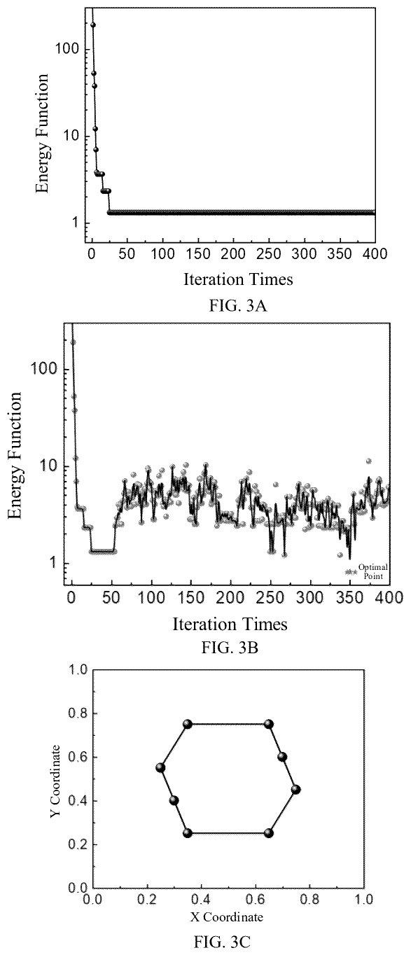

FIG. 3 schematically shows an optimization effect of the Hopfield network in solving a traveling salesman problem according to the embodiments of the present disclosure.

According to the embodiments of the present disclosure, in a case that the recursive neural network is the Hopfield network, when using the Hopfield network to perform optimization problems, such as designing a traveling salesman problem of 8 cities, the Hopfield network is used to solve an optimal path. In the absence of disturbances, the Hopfield network often falls into a local optimal solution when solving optimization problems, as shown in FIG. 3(a), which may not obtain a global optimal solution. In the present disclosure, a weight of the Hopfield network is mapped to the spintronic device 100 with four nodes. Due to anisotropic disturbances and fluctuations in the device multiplication and addition process, the device may jump out of the local optimal value and achieve the global optimal solution during an iteration process, as shown in FIG. 3(b). FIG. 3(c) shows the optimal solution for the traveling salesman problem of 8 cities obtained by the spintronic device 100 after introducing a Gaussian wave with an average value of 0 and σ²=2.

FIG. 4 schematically shows a weight modulation diagram of the Hopfield network according to the embodiments of the present disclosure.

According to the embodiments of the present disclosure, FIG. 4 shows a weight modulation method and principle of the spintronic device 100 when solving the problem of the Hopfield network. In an absence of initial external excitation, the magnetic layer of the spintronic device 100 has a randomly distributed labyrinth-like magnetic domain structure, as shown on the surface of the spintronic device 100 in FIG. 1. At this point, a resistivity ρ_{⊥} (ρ_{∥}) of the spintronic device 100 perpendicular to (parallel to) the current is composed of an intrinsic resistivity ρₛ, a magnetic domain wall resistivity ρ_{cpw} (ρ_{ciw}) and an anisotropic magnetoelectric resistance ρₐₘᵣ, please refer to equations (1) and (2).

$${ρ}_{⊥} = {ρ}_{s} + \frac{δ}{d} {ρ}_{cpw} + {ρ}_{amr ⊥} \qquad ( 1 )$$

$${ρ}_{\vert \vert} = {ρ}_{s} + \frac{δ}{d} {ρ}_{ciw} + {ρ}_{amr \vert \vert} \qquad ( 2 )$$

where δ is a width of the magnetic domain wall, and d is a size of the magnetic domain.

According to the embodiments of the present disclosure, under a condition of no external field, applying a current pulse may regulate the increase or decrease of the conductivity of the spintronic device 100. As shown in FIG. 4, for a structure of a device 400 (i.e. the spintronic device 100), the current pulse (a current density is 2×10¹¹ A/m, and a pulse width is 10 ns) is applied at two ends 401 and 404. A magnetic domain structure of a magnetic domain wall in the device 400 changes under a combined action of a spin transfer torque (STT) and a spin orbit torque (SOT) (mainly SOT). The magnetic domain wall is perpendicular to the current direction, resulting in ρₐₘᵣ changes. A resistance measurement is conducted at two ends 401 and 404, and a resistance value is 757.59Ω, having a decrease of 6.04Ω compared to when no current is applied. A light-colored current density distribution in 401 also reveals the presence of more high current density channels in the device. A resistance measurement is conducted at twos ends 402 and 403, and a resistance value is 769.17Ω, having an increase of 7.11Ω compared to when no current is applied. A dark current density distribution in 402 also reveals the presence of more low current density channels in the device.

According to the embodiments of the present disclosure, scale bars on the right side of (b) and (c) of FIG. 4 represent the current density. By comparing the two, it may be seen that an area of a dark part in (c) is greater than that in (b). Therefore, it is determined that the current density of the device 400 in (c) is less than that in (b), so as to determine that a resistance value of the device 400 in (c) is higher.

According to the embodiments of the present disclosure, by driving the labyrinth-like magnetic domain structure through a fully electronically controlled SOT, the reduction or increase of multivalued weights is achieved, so as to be closer to a learning rule of Hebbian and anti-Hebbian in the human brain. Due to the anisotropic magnetoresistance (AMR) of the array based on the spintronic device and reading fluctuations, the local optimal solution in the process of optimizing the recursive neural network (such as the Hopfield network) is got rid of, so as to achieve the global optimal solution.

The above are only preferred embodiments of the present disclosure and are not intended to limit the present disclosure. Any modifications, equivalent substitutions, improvements, etc. made within the spirit and principles of the present disclosure shall be included in the scope of protection of the present disclosure.

1. A spintronic device based on a magnetic domain wall, comprising:
a magnetic domain device, wherein the magnetic domain device is configured to form a labyrinth-like magnetic domain structure under a modulation of a Dzyaloshinskii-Moriya interaction and a dipole interaction, the labyrinth-like magnetic domain structure comprises a plurality of magnetic domain regions located randomly, and a boundary between adjacent two magnetic domain regions is the magnetic domain wall;
a heterogenous thin film of at least one cycle, wherein the heterogenous thin film is disposed on a first surface of the magnetic domain device;
at least four electrodes disposed on a second surface of the magnetic domain device, wherein the four electrodes are respectively connected to different magnetic domain regions.

2. The spintronic device according to claim 1, wherein the magnetic domain device comprises a heavy metal layer and a magnetic layer with a preset thickness, wherein a range of the preset thickness of the magnetic layer is 1.1 nm to 1.4 nm, a heterostructure composed of the magnetic layer and the heavy metal layer is configured to generate the Dzyaloshinskii-Moriya interaction and the dipole interaction, so as to generate the labyrinth-like magnetic domain structure in a transition region of vertical anisotropy and in-plane anisotropy.

3. The spintronic device according to claim 2, wherein the heterostructure further comprises a barrier layer, and the barrier layer is disposed on a surface of the magnetic layer close to the electrode.

4. The spintronic device according to claim 3, wherein the magnetic domain device comprises at least two heterostructures stacked periodically.

5. The spintronic device according to claim 2, wherein the heavy metal layer is made of at least one of: Pt, W, Ta, Ru, Au, Ir, or Pd;
the magnetic layer is made of at least one of: CoFeB, CoFe, NiFe, IrMn, GdFeCo, Co, Fe, two-dimensional CrI₃, or Fe₃GeTe₂;
in a case that the magnetic domain device comprises a barrier layer, the barrier layer is made of at least one of: MgO, AlₓO_{y}, or h-BN, wherein each of x and y is an integer greater than 0.

6. An array based on a spintronic device, comprising:
a plurality of line groups arranged horizontally spaced, wherein each of the plurality of line groups comprises a source line, a first word line and a second word line arranged horizontally from top to bottom, and the first word line and the second word line are spaced at a preset distance;
a plurality of bit lines arranged vertically spaced, wherein two adjacent bit lines, and the first word line and the second word line in each line group form a placement region;
a plurality of spintronic devices according to claim 1, wherein one spintronic device is disposed in each placement region;
wherein a connection method of the spintronic device and the line group and bit line corresponding to the placement region comprises:
at least two of at least four electrodes are connected to one bit line, remaining at least two of the at least four electrodes are respectively connected to the source line and the second word line in one line group, and the at least two electrodes connected to the bit line are respectively connected to the first word line and the second word line.

7. The array according to claim 6, wherein the at least two electrodes connected to the bit line are respectively connected to the first word line and the second word line through a transistor.

8. The array according to claim 6, wherein the electrode connected to the bit line and the first word line is connected to the spintronic device through a first connection point on the spintronic device, and the electrode connected to the source line is connected to the spintronic device through a second connection point on the spintronic device;
the electrode connected only to the second word line is connected to the spintronic device through a third connection point on the spintronic device, and the electrode connected to the bit line and the second word line is connected to the spintronic device through a fourth connection point on the spintronic device.

9. A method for optimizing a recursive neural network implemented in hardware, applied to the array according to claim 6, wherein a weight of the recursive neural network is mapped to the array, the array stores the weight of the recursive neural network, and the method comprises:
for each spintronic device in the array, when the first word line connected to the spintronic device is at a high level and the bit line is grounded, an electrical pulse in the source line drives a motion of the magnetic domain wall through a first node and a second node, so as to reduce the weight of the recursive neural network, wherein the first node refers to a connection point of the electrode connected to the bit line and the first word line on the spintronic device, and the second node refers to a connection point of the electrode connected to the source line on the spintronic device;
when the second word line is at a high level and the bit line is grounded, the electrical pulse in the source line drives the motion of the magnetic domain wall through a third node and a fourth node, so as to increase the weight of the recursive neural network, wherein the third node refers to a connection point of the electrode connected only to the second word line on the spintronic device, and the fourth node refers to a connection point of the electrode connected to the bit line and the second word line on the spintronic device.
